(19) United States
(12) Patent Application Publication
(10) Pub. No.: US 2023/0215959 A1
(43) Pub. Date: Jul. 6, 2023

(54) PHOTOELECTRIC CONVERSION APPARATUS, PHOTOELECTRIC CONVERSION SYSTEM, AND MOVING BODY

(71) Applicant: CANON KABUSHIKI KAISHA, Tokyo (JP)

(72) Inventors: HIROSHI SEKINE, Kanagawa (JP); KAZUHIRO MORIMOTO, Kanagawa (JP)

(21) Appl. No.: 18/149,572

(22) Filed: Jan. 3, 2023

(30) Foreign Application Priority Data
Jan. 5, 2022 (JP) 2022-000315

(51) Int. Cl. H01L 31/02; H01L 31/107

(52) U.S. Cl. CPC H01L 31/02005; H01L 31/107

(57) ABSTRACT

A photoelectric conversion apparatus comprising an avalanche diode disposed in a semiconductor layer having a first surface and a second surface, wherein the avalanche diode includes a first semiconductor region disposed at a first depth, a second semiconductor region disposed at a second depth deeper from the second surface than the first depth, a third semiconductor region disposed at an edge of the first semiconductor region, a first wiring connected to the first semiconductor region, a second wiring connected to the second semiconductor region, and a third wiring not connected to the semiconductor layer, at least a part of the third wiring overlapping with the third semiconductor region in a planar view, and wherein a third voltage to be supplied to the third wiring is a value between a first voltage to be supplied to the first wiring and a second voltage to be supplied to the second wiring.

### BACKGROUND OF THE DISCLOSURE

### Field of the Disclosure

The present disclosure relates to a photoelectric conversion apparatus, a photoelectric conversion system, and a moving body.

### Description of the Related Art

A photoelectric conversion apparatus having a reflecting plate in the wiring layer improves the quantum conversion efficiency. The reflecting plate reflects incident light that has penetrated a semiconductor substrate to extend the optical path length of the incident light in a photoelectric conversion element. United States Patent Application Publication No. 2020/0286946 discusses a single-photon avalanche diode (SPAD) having an anode wiring used as a reflecting plate. Likewise, United States Patent Application Publication No. 2019/0181177 discusses a single-photon avalanche diode (SPAD) having an extended anode wiring.

In a structure discussed in United States Patent Application Publication No. 2020/0286946, a cathode wiring exists right above the guard ring region. Accordingly, there has been an issue that, if a hot carrier is trapped in the vicinity of the cathode region, the potential around an intense electric field region changes to change the breakdown voltage over time. In a structure discussed in United States Patent Application Publication No. 2019/0181177, an anode wiring exists right above the guard ring region. Accordingly, there has been a concern that the electric field concentrates at the edge of the cathode region to increase the Dark Count Rate (DCR).

There is a need in the art to reduce the breakdown voltage variation over time by the injection of the hot carrier into the semiconductor substrate boundary surface while restraining the DCR.

### SUMMARY OF THE DISCLOSURE

According to an aspect of the present disclosure, a photoelectric conversion apparatus comprising an avalanche diode disposed in a semiconductor layer having a first surface and a second surface facing the first surface, wherein the avalanche diode includes a first semiconductor region of a first conductivity type disposed at a first depth, a second semiconductor region of a second conductivity type disposed at a second depth deeper from the second surface than the first depth, a third semiconductor region disposed at an edge of the first semiconductor region in a planar view, a first wiring connected to the first semiconductor region, a second wiring connected to the second semiconductor region, and a third wiring not connected to the semiconductor layer, at least a part of the third wiring overlapping with the third semiconductor region in a planar view, and wherein a third voltage to be supplied to the third wiring is a value between a first voltage to be supplied to the first wiring and a second voltage to be supplied to the second wiring.

Further features of the present disclosure will become apparent from the following description of exemplary embodiments with reference to the attached drawings.

### BRIEF DESCRIPTION OF THE DRAWINGS

FIG. 1 schematically illustrates a photoelectric conversion apparatus according to an exemplary embodiment.

FIG. 2 schematically illustrates a photodiode (PD) substrate of the photoelectric conversion apparatus according to an exemplary embodiment.

FIG. 3 schematically illustrates a circuit substrate of the photoelectric conversion apparatus according to an exemplary embodiment.

FIG. 4 illustrates an example of a configuration of a pixel circuit of the photoelectric conversion apparatus according to an exemplary embodiment.

FIGS. 5A to 5C are schematic views illustrating a drive of the pixel circuit of the photoelectric conversion apparatus according to an exemplary embodiment.

FIG. 6 is a cross-sectional view illustrating a photoelectric conversion element according to a first exemplary embodiment.

FIGS. 7A and 7B are plan views illustrating the photoelectric conversion element according to the first exemplary embodiment.

FIG. 8 illustrates a potential of the photoelectric conversion element according to the first exemplary embodiment.

FIGS. 9A and 9B illustrate a potential and an electric field intensity, respectively, of the photoelectric conversion element according to the first exemplary embodiment.

FIG. 10 illustrates an example of a voltage setting of the photoelectric conversion element according to the first exemplary embodiment.

FIG. 11 illustrates a cross-sectional diagram of a photoelectric conversion element according to a second exemplary embodiment.

FIG. 12 illustrates a cross-sectional diagram of a photoelectric conversion element according to a third exemplary embodiment.

FIG. 13 illustrates a cross-sectional diagram of a photoelectric conversion element according to a fourth exemplary embodiment.

FIG. 14 is a functional block diagram of a photoelectric conversion system according to a fifth exemplary embodiment.

FIGS. 15A and 15B are functional block diagrams of a photoelectric conversion system according to a sixth exemplary embodiment.

FIG. 16 is a functional block diagram of a photoelectric conversion system according to a seventh exemplary embodiment.

FIG. 17 is a functional block diagram of a photoelectric conversion system according to an eighth exemplary embodiment.

FIGS. 18A and 18B each are a functional block diagram of a photoelectric conversion system according to a ninth exemplary embodiment.

### DESCRIPTION OF THE EMBODIMENTS

The following exemplary embodiments are not intended to limit the present disclosure but intended to embody the technical concepts of the present disclosure. In each drawing, the sizes and positional relations of members may be emphasized to clarify the descriptions. In the following descriptions, identical components are assigned the same reference numerals, and redundant descriptions thereof may be omitted.

Exemplary embodiments of the present disclosure will be described in detail below with reference to the accompanying drawings. In the following descriptions, terms indicating a specific direction or position (e.g., “upper”, “lower”, “right”, “left”, and other terms including these terms) are used as required. The use of these terms is intended to facilitate the understanding of exemplary embodiments to be described below with reference to drawings, and the technical scope of the present disclosure is not to be limited by the meanings of these terms.

According to the present disclosure, a planar view refers to viewing from a direction perpendicular to the light incidence surface of a semiconductor layer. A cross-sectional view refers to a plane perpendicular to the light incidence surface of the semiconductor layer. If the light incidence surface of the semiconductor layer is a coarse surface when microscopically viewed, a planar view is defined with reference to the light incidence surface of the semiconductor layer when macroscopically viewed.

In the following discussions, the anode of an avalanche photodiode (APD) is set to a fixed potential and a signal is taken out from the cathode side. Therefore, a semiconductor region of the first conductivity type including electric charges, as the major carrier, having the same polarity as signal electric charges is an N-type semiconductor region, and a semiconductor region of the second conductivity type including electric charges, as the major carrier, having the different polarity from signal electric charges is a P-type semiconductor region. The present disclosure is implemented even in a case where the cathode of the APD is set to a fixed potential and a signal is taken out from the anode side. In this case, a semiconductor region of the first conductivity type including electric charges, as the major carrier, having the same polarity as signal electric charges is a P-type semiconductor region, and a semiconductor region of the second conductivity type including electric charges, as the major carrier, having the different polarity from signal electric charges is an N-type semiconductor region. Although, in the following descriptions, one node of the APD is set to a fixed potential, the potential of the two nodes may vary.

According to the present disclosure, the term “impurity density” simply used means the net impurity density after the deduction of the value compensated by the impurity of the opposite conductivity type. More specifically, the term “impurity density” refers to the net doping density. A region where the P-type additive impurity density is higher than the N-type additive impurity density is a P-type semiconductor region. Conversely, a region where the N-type additive impurity density is higher than the P-type additive impurity density is an N-type semiconductor region.

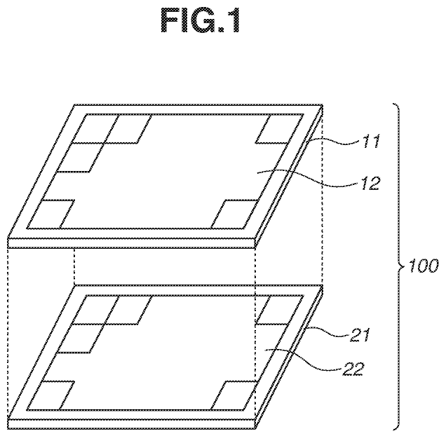

Configurations common to each exemplary embodiment of a photoelectric conversion apparatus and a method for driving the apparatus according to the present disclosure will be described below with reference to FIGS. 1 to 5C.

FIG. 1 illustrates a configuration of a lamination type photoelectric conversion apparatus 100 according to an exemplary embodiment of the present disclosure.

The photoelectric conversion apparatus 100 includes a sensor substrate 11 and a circuit substrate 21 which are stacked in layers and electrically connected with each other. The sensor substrate 11 includes a first semiconductor layer having a photoelectric conversion element 102 (described below) and a first wiring structure. The circuit substrate 21 includes a second semiconductor layer having such a circuit as a signal processing unit 103 (described below) and a second wiring structure. The photoelectric conversion apparatus 100 includes the second semiconductor layer, the second wiring structure, the first wiring structure, and the first semiconductor layer stacked in layers in this order. The photoelectric conversion apparatus 100 according to each exemplary embodiment is a rear surface irradiation photoelectric conversion apparatus where light is incident on a first surface and the circuit substrate 21 is disposed on a second surface.

Although the sensor substrate 11 and the circuit substrate 21 will be described below as diced chips, the configuration is not limited to chips. For example, each substrate may be a wafer. These substrates may be stacked in a wafer state and then diced, or may be chipped and then bonded in a state where chips are stacked.

The sensor substrate 11 is provided with a pixel region 12, and the circuit substrate 21 is provided with a circuit region 22 for processing signals detected in the pixel region 12.

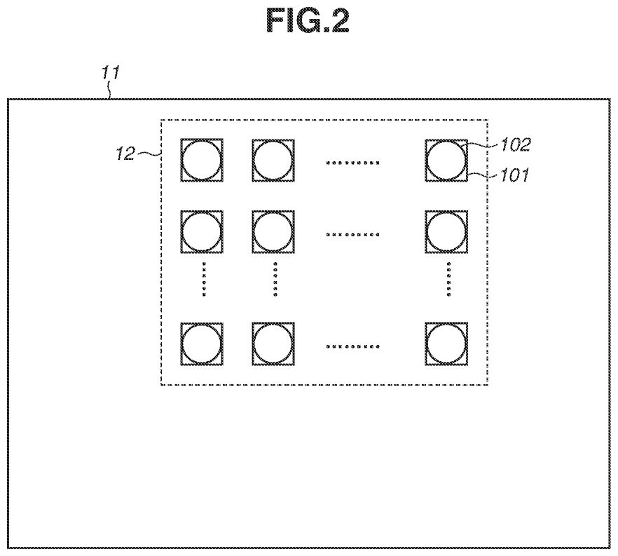

FIG. 2 illustrates an example configuration of the sensor substrate 11. Pixels 101 each having a photoelectric conversion element 102 including an avalanche photodiode (hereinafter referred to as an APD) are arranged in a two-dimensional array form in a planar view to form the pixel region 12.

Although the pixels 101 are typically pixels for forming an image, the pixels 101 do not necessarily need to form an image when used in Time of Flight (ToF). More specifically, the pixels 101 may be pixels for measuring the arrival time of light and the light quantity.

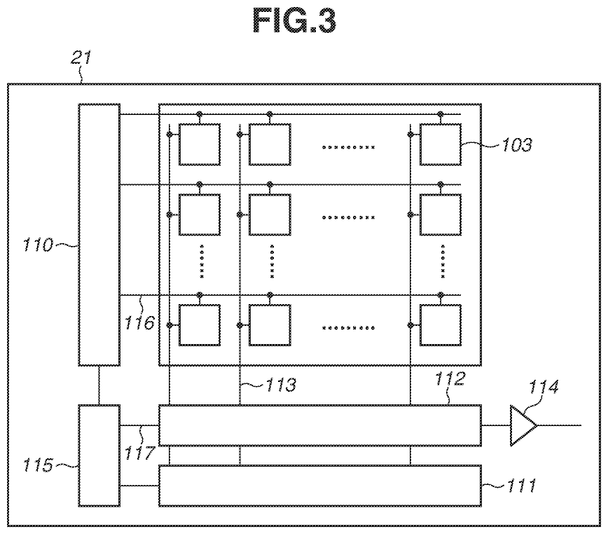

FIG. 3 illustrates a configuration of the circuit substrate 21. The circuit substrate 21 includes signal processing units 103 that process electric charges generated through the photoelectric conversion by the photoelectric conversion elements 102 in FIG. 2, a read circuit 112, a control pulse generation unit 115, a horizontal scanning circuit unit 111, signal lines 113, and a vertical scanning circuit unit 110.

The photoelectric conversion element 102 in FIG. 2 and the signal processing unit 103 in FIG. 3 are electrically connected with each other through a connection wiring provided for each pixel 101.

The vertical scanning circuit unit 110 receives a control pulse supplied from the control pulse generation unit 115 and supplies the control pulse to each pixel 101. Logic circuits such as a shift register and an address decoder are used as the vertical scanning circuit unit 110.

The signal output from the photoelectric conversion element 102 of each pixel 101 is processed by the signal processing unit 103. The signal processing unit 103 includes a counter and a memory that stores a digital value.

The horizontal scanning circuit unit 111 inputs a control pulse for sequentially selecting each column to the signal processing unit 103 to read the signal from the memory of each pixel 101 storing a digital signal.

For a selected column, the signal processing unit 103 of the pixel 101 selected by the vertical scanning circuit unit 110 outputs a signal to the signal line 113.

The signal output to the signal line 113 is output to a recording unit or a signal processing unit outside the photoelectric conversion apparatus 100 via an output circuit 114.

Referring to FIG. 2, the array of the photoelectric conversion elements 102 in the pixel region 12 may be one-dimensionally arranged. The effect of the present disclosure can be obtained even in a case of one pixel, which is also included in the present disclosure. Not all of the photoelectric conversion elements 102 need to be provided with the function of the signal processing unit 103. For example, a plurality of photoelectric conversion elements 102 may share one signal processing unit and perform signal processing in a sequential way.

As illustrated in FIGS. 2 and 3, a plurality of the signal processing units 103 is disposed in the region overlapping with the pixel region 12 in a planar view. The vertical scanning circuit unit 110, the horizontal scanning circuit unit 111, a row circuit 112, the output circuit 114, and the control pulse generation unit 115 are disposed in an overlapped way between the edges of the sensor substrate 11 and the edges of the pixel region 12 in a planar view. In other words, the sensor substrate 11 includes the pixel region 12, and a non-pixel region disposed around the pixel region 12. The vertical scanning circuit unit 110, the horizontal scanning circuit unit 111, the column circuit 112, the output circuit 114, and the control pulse generation unit 115 are disposed in the region overlapping with the non-pixel region in a planar view.

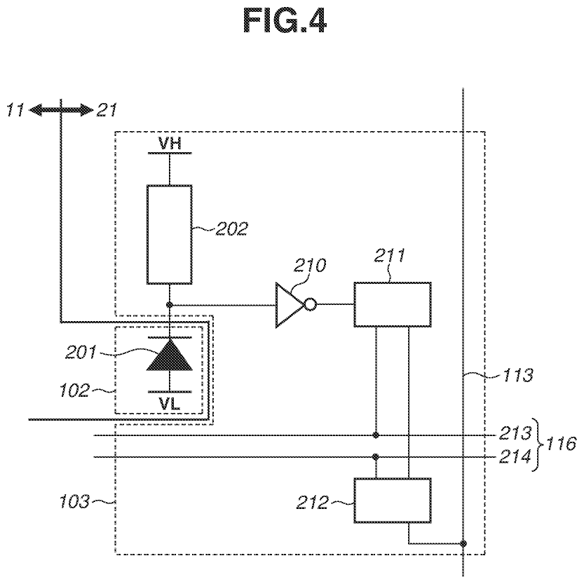

FIG. 4 illustrates an example of a block diagram including equivalent circuits of the substrates in FIGS. 2 and 3.

The photoelectric conversion elements 102 each having an APD 201 are disposed on the sensor substrate 11 in FIG. 2, and other members are disposed on the circuit substrate 21.

The APD 201 generates a charge pair corresponding to incident light through the photoelectric conversion. The anode of the APD 201 is supplied with a voltage VL (first voltage). The cathode of the APD 201 is supplied with a voltage VH (second voltage) that is higher than the voltage VL supplied to the anode. The anode and the cathode are supplied with reverse bias voltages so that the APD 201 performs the avalanche multiplication operation. Supplying such voltages causes the avalanche multiplication of electric charges generated by incident light, and generates an avalanche current.

When a reverse bias voltage is supplied, the APD 201 is operated in the Geiger or linear mode. In the Geiger mode, the APD 201 is operated with a potential difference between the anode and the cathode larger than the breakdown voltage. In the linear mode, the APD 201 is operated with a potential difference between the anode and the cathode close to, or equal to or less than the breakdown voltage.

An APD 201 operated in the Geiger mode is referred to as a single-photon avalanche diode (SPAD). For example, the voltage VL (first voltage) is −30 V, and the voltage VH (second voltage) is 1 V. The APD 201 may be operated in either the linear or the Geiger mode. It is desirable that the APD 201 is a SPAD having a larger potential difference and providing a more remarkable effect of the withstand voltage than the APD 201 in the linear mode.

A quench element 202 is connected to the power source for supplying the voltage VH and the APD 201. The quench element 202 functions as a load circuit (quench circuit) during signal multiplication by the avalanche multiplication. More specifically, the quench element 202 has a function of restraining the voltage to be supplied to the APD 201 to restrain the avalanche multiplication (quench operation). The quench element 202 also has a function of returning the voltage to be supplied to the APD 201 to the voltage VH by applying a current corresponding to the voltage drop in the quench operation (recharge operation).

The signal processing unit 103 includes a waveform shaping unit 210, a counter circuit 211, and a selection circuit 212. According to the present disclosure, the signal processing unit 103 needs to include any one of the waveform shaping unit 210, the counter circuit 211, and the selection circuit 212.

The waveform shaping unit 210 shapes the potential variation of the cathode of the APD 201 obtained in photon detection, and outputs a pulse signal. For example, an inverter circuit is used as the waveform shaping unit 210. Although, in the example in FIG. 4, one inverter is used as the waveform shaping unit 210, a circuit formed of a plurality of inverters connected in series or other circuits having a waveform shaping effect are also applicable.

The counter circuit 211 counts the pulse signal output from the waveform shaping unit 210 and holds the count value. When a control pulse pRES is supplied via a drive line 213, the signal held by the counter circuit 211 is reset.

The selection circuit 212 is supplied with a control pulse pSEL from the vertical scanning circuit unit 110 in FIG. 3 via a drive line 214 in FIG. 4 (not illustrated in FIG. 3) to electrically connect or disconnect between the counter circuit 211 and the signal line 113. The selection circuit 212 includes, for example, a buffer circuit for outputting a signal.

A switch such as a transistor may be disposed between the quench element 202 and the APD 201 and between the photoelectric conversion element 102 and the signal processing unit 103 to change the electrical connection. Likewise, the supply of the voltage VH or VL to the photoelectric conversion element 102 may be electrically changed by using a switch such a transistor.

The present exemplary embodiment has been described above centering on a configuration using the counter circuit 211. However, instead of using the counter circuit 211, the photoelectric conversion apparatus 100 may acquire the pulse detection timing by using a Time to Digital Converter (hereinafter referred to as a TDC) and a memory. In this case, the generation timing for the pulse signal output from the waveform shaping unit 210 is converted into a digital signal by the TDC. For the measurement of the timing for the pulse signal, the TDC is supplied with a control pulse pREF (reference signal) from the vertical scanning circuit unit 110 in FIG. 1 via a drive wire. The TDC acquires, as a digital signal, a signal when the input timing for the signal output from each pixel via the waveform shaping unit 210 is assumed as a relative time, with reference to the control pulse pREF.

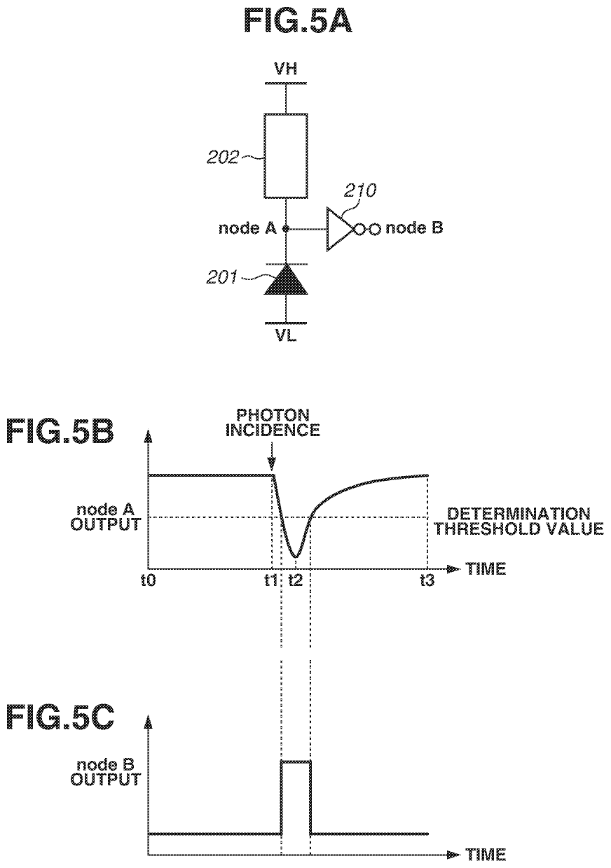

FIGS. 5A, 5B, and 5C schematically illustrate a relation between the APD operation and the output signal.

FIG. 5A illustrates an extraction of the APD 201, the quench element 202, and the waveform shaping unit 210 in FIG. 4. The input side of the waveform shaping unit 210 is referred to as a node A, and the output side thereof is referred to as a node B. FIG. 5B illustrates a waveform variation at the node A in FIG. 5A, and FIG. 5C illustrates a waveform variation at the node B in FIG. 5A.

Referring to FIG. 5A, during the time period between the time t0 and the time t1, the potential difference between VH and VL is applied to the APD 201. When photons are incident on the APD 201 at the time t1, the avalanche multiplication occurs in the APD 201, an avalanche multiplication current flows in the quench element 202, and a voltage drop occurs at the node A. When the amount of voltage drop further increases to decrease the potential difference applied to the APD 201, the avalanche multiplication of APD 201 stops at the time t2. When the voltage level at the node A drops by a predetermined value, it does not drop any more. Then, during the time period between the time t3 and the time t2, a current for compensating the voltage drop from the voltage VL flows at the node A. At the time t3, the voltage level at the node A returns to the former potential level. At this timing, the portion of the output waveform exceeding a threshold value at the node A is shaped by the waveform shaping unit 210 and then output as a signal at the node B.

The arrangements of the signal lines 113, the column circuit 112, and the output circuit 114 are not limited to the circuit in FIG. 3. For example, the signal lines 113 are extended in the row direction. The column circuit 112 may be disposed at a position where the signal lines 113 are extended to.

The photoelectric conversion apparatus 100 according to each exemplary embodiment will be described below.

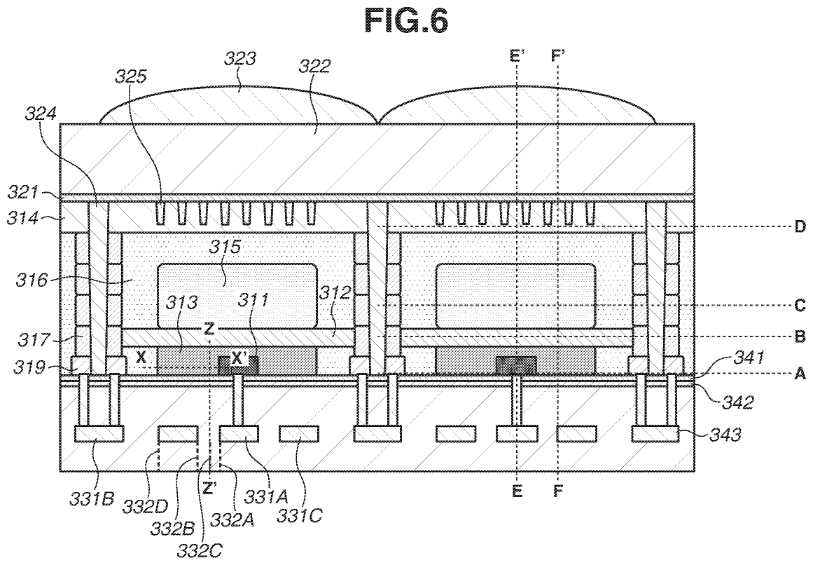

The photoelectric conversion apparatus 100 according to a first exemplary embodiment will be described below with reference to FIGS. 6 to 10.

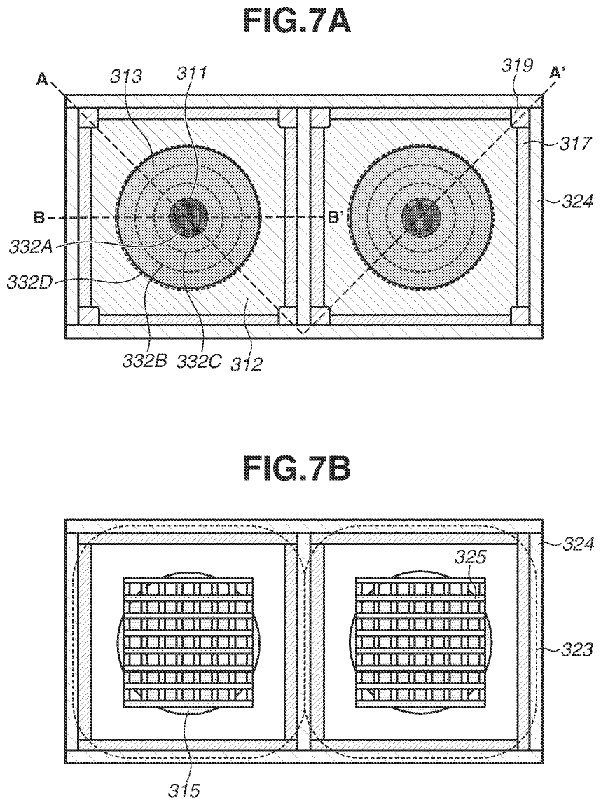

FIG. 6 is a cross-sectional view illustrating two adjacent pixels for the photoelectric conversion elements 102 of the photoelectric conversion apparatus 100 according to the first exemplary embodiment, taken along a direction perpendicular to the planar direction of the substrate. FIG. 6 corresponds to the A-A′ cross-section in FIG. 7A.

The structure and function of the photoelectric conversion element 102 will be described below. The photoelectric conversion element 102 includes a first semiconductor region 311, a third semiconductor region 313, a fifth semiconductor region 315, and a sixth semiconductor region 316 which are of the N type. The photoelectric conversion element 102 further includes a second semiconductor region 312, a fourth semiconductor region 314, a seventh semiconductor region 317, and a ninth semiconductor region 319 which are of the P type.

According to the present exemplary embodiment, in the cross section illustrated in FIG. 6, the N-type first semiconductor region 311 is formed in the vicinity of the surface facing the light incidence surface, and the N-type third semiconductor region 313 is formed around the first semiconductor region 311. The P-type second semiconductor region 312 is formed at a position overlapping with the first semiconductor region 311 and the third semiconductor region 313 in a planar view. The N-type fifth semiconductor region 315 is disposed at a position overlapping with the second semiconductor region 312 in a planar view, and the N-type sixth semiconductor region 316 is formed around the fifth semiconductor region 315.

The first semiconductor region 311 has a higher N-type impurity density than the third semiconductor region 313 and the fifth semiconductor region 315. A PN junction is formed between the P-type second semiconductor region 312 and the N-type first semiconductor region 311. All regions overlapping with the center of the first semiconductor region 311 in a planar view, out of the second semiconductor region 312, are formed as depletion regions by making the impurity density of the second semiconductor region 312 lower than the impurity density of the first semiconductor region 311. In this case, the potential difference between the first semiconductor region 311 and the second semiconductor region 312 is larger than the potential difference between the second semiconductor region 312 and the fifth semiconductor region 315. Further, this depletion region extends to a part of the first semiconductor region 311, and an intense electric field is induced in the extended depletion region. This intense electric field causes the avalanche multiplication in the depletion region extending to a part of the first semiconductor region 311, and a current based on amplified electric charges is output as signal electric charges. When the light incident on the photoelectric conversion element 102 is photoelectrically converted, and the avalanche multiplication takes place in the depletion region (avalanche multiplication region), generated electric charges of the first conductivity type are collected in the first semiconductor region 311.

Although, referring to FIG. 6, the third semiconductor region 313 and the fifth semiconductor region 315 are formed in almost the same size, the size of each semiconductor region is not limited thereto. For example, the fifth semiconductor region 315 may be formed to be larger than the third semiconductor region 313 to collect electric charges from a wider range to the first semiconductor region 311.

The third semiconductor region 313 may be a P-type semiconductor region, not an N-type semiconductor region.

In this case, the impurity density of the third semiconductor region 313 is set to be lower than the impurity density of the second semiconductor region 312. If the impurity density of the third semiconductor region 313 is too high, an avalanche multiplication region is formed between the third semiconductor region 313 and the first semiconductor region 311, resulting an increase in the Dark Count Rate (DCR).

A trench-based concavo-convex structure 325 is formed on the front surface on the light incidence side of the semiconductor layer. The concavo-convex structure 325 surrounded by the P-type fourth semiconductor region 314 scatters the light incident on the photoelectric conversion element 102. Since the incident light obliquely advances through the photoelectric conversion element 102, an optical path length equal to or larger than the thickness of a semiconductor layer 301 can be secured. This makes it possible to photoelectrically convert light with a longer wavelength than in a case where the concavo-convex structure 325 is not provided. The concavo-convex structure 325 prevents the incident light reflection in the substrate, making it possible to obtain an effect of improving the photoelectric conversion efficiency for incident light. Further, by combining the concavo-convex structure 325 with a third wiring 331C having a shape to cover the surface facing the light incidence surface of the semiconductor substrate which characterizes the present disclosure of the present application, the third wiring 331C efficiently reflects light obliquely diffracted by the concavo-convex structure 325, thus further improving the near-infrared sensitivity. The concavo-convex structure 325 is not an indispensable component to the present disclosure of the present application. The effect of the present disclosure of the present application can be obtained even with a photoelectric conversion element in which the concavo-convex structure 325 is not formed.

The fifth semiconductor region 315 and the concavo-convex structure 325 are formed to overlap with each other in a planar view. The area of the portion of the fifth semiconductor region 315 overlapping with the concavo-convex structure 325 in a planar view is larger than the area of the portion of the fifth semiconductor region 315 not overlapping with the concavo-convex structure 325. The moving time until electric charges generated at far positions from the avalanche multiplication region formed between the first semiconductor region 311 and the fifth semiconductor region 315 reach the avalanche multiplication region is longer than the moving time until electric charges generated at near positions from the avalanche multiplication region reach the avalanche multiplication region. Therefore, the timing jitter may possibly increase. Disposing the fifth semiconductor region 315 and the concavo-convex structure 325 at positions where they overlap with each other in a planar view enables increasing the electric field at the deep portion of the photodiode. This enables reducing the time for collecting electric charges generated at far positions from the avalanche multiplication region, thus reducing the timing jitter.

The fourth semiconductor region 314 that three-dimensionally covers the concavo-convex structure 325 enables restraining the generation of thermal excitation electric charges at the boundary portion of the concavo-convex structure 325. This restrains the DCR of the photoelectric conversion element 102.

Pixels are separated by a pixel separation portion 324 having a trench structure. The P-type seventh semiconductor region 317 formed around the pixel separation portion 324 separates adjacent photoelectric conversion elements 102 by a potential barrier. Since the photoelectric conversion elements 102 are also separated by the potential of the seventh semiconductor region 317, such a trench structure as the pixel separation portion 324 has is not essential for pixel separation portions. When disposing the pixel separation portion 324 having the trench structure, the depth and position thereof are not limited to the configuration in FIG. 6. The pixel separation portion 324 may be a deep trench isolation (DTI) that penetrates through the semiconductor layer or a DTI that does not penetrate through the semiconductor layer. A metal may be embedded in the DTI to improve the light shielding performance. The pixel separation portion 324 may be made of a SiO, a fixed charge film, a metallic material, polysilicon, or a combination of a plurality of these components. The pixel separation portion 324 may be configured to surround the entire circumference of the photoelectric conversion element 102 in a planar view. For example, the pixel separation portion 324 may be configured only at the opposite side portion of the photoelectric conversion element 102. A voltage may be applied to an embedded material to induce electric charges on the trench boundary surface, thus restraining the DCR.

The distance from the pixel separation portion 324 of a pixel to the pixel separation portion 324 of an adjacent pixel or the pixel disposed at the closest position can also be recognized as the size of one photoelectric conversion element 102. When one photoelectric conversion element 102 has a size L, a distance d from the light incidence surface to the avalanche multiplication region satisfies L√2/4<d<L*√2. When the size and depth of the photoelectric conversion element 102 satisfy this relational expression, the electric field intensity in the depth direction is almost the same as the electric field intensity in the planer direction in the vicinity of the first semiconductor region 311. The above-described configuration can restrain variations of the time for collecting electric charges, making it possible to improve the timing jitter.

A pinning film 321, a planarizing film 322, and a microlens 323 are further formed on the light incidence surface side of the semiconductor layer. A filter layer (not illustrated) may be further disposed on the light incidence surface side. Various types of optical filters such as a color filter, an infrared cut filter, and a monochromatic filter can be used as the filter layer. Examples of color filters include a red, green, and blue (RGB) color filter and a read, green, blue, and white (RGBW) color filter.

The surface facing the light incidence surface of the semiconductor layer is provided with a wiring structure including a conductor and an insulation film. The photoelectric conversion element 102 illustrated in FIG. 6 includes an oxide film 341 and a protection film 342 from the side closer to the semiconductor layer, and further includes wiring layers made of conductors stacked in layers on top of each other. An interlayer film 343 as an insulation film is provided between a wiring layer and the semiconductor layer and between the wiring layers. The protection film 342 protects the avalanche diode from plasma damages and metallic contamination at the time of etching.

Although it is common to use SiN as a nitride film, SiON, SiC, or SiCN are also applicable.

A cathode wiring 331A (first wiring) is connected to the first semiconductor region 311 to supply a cathode voltage (first voltage). An anode wiring 331B (second wiring) supplies an anode voltage (second voltage) to the seventh semiconductor region 317 via the ninth semiconductor region 319 as an anode contact. The third wiring 331C is disposed between the cathode wiring 331A and the anode wiring 331B, and is supplied with a third voltage that is higher than the anode voltage and lower than the cathode voltage. More specifically, the third voltage is set to a value between the cathode voltage (first voltage) and the anode voltage (second voltage). When the first semiconductor region 311 is a P-type semiconductor region, and the second semiconductor region 312 is an N-type semiconductor region, the third wiring 331C is supplied with the third voltage that is higher than the anode voltage and lower than the cathode voltage.

According to the present exemplary embodiment, the cathode wiring 331A, the anode wiring 331B, and the third wiring 331C are formed in the same wiring layer. The wiring includes conductors containing metals such as Cu and Al. This cross-section includes a cathode wiring outer periphery portion 332A and an inner periphery portion 332B of the third wiring 331C facing the cathode wiring outer periphery portion 332A. A dotted line 332C is a virtual line that internally equally divides the distance between the cathode wiring outer periphery portion 332A and the inner periphery portion 332B of the third wiring 331C. Further, a dotted line 332D is the outer periphery portion of the third wiring 331C facing the anode wiring 331B.

FIGS. 7A and 7B are plan views illustrating two adjacent pixels of the photoelectric conversion element 102 according to the first exemplary embodiment. FIG. 7A is a plan view of the photoelectric conversion element 102 in a planar view from the surface facing the light incidence surface, and FIG. 7B is a plan view of the photoelectric conversion element in a planar view from the light incidence surface side.

Referring to FIG. 7A, the first semiconductor region 311, the third semiconductor region 313, and the fifth semiconductor region 315 have a circular shape and are concentrically disposed. This structure enables preventing the electric field from locally concentrating at the edge of the intense electric field region between the first semiconductor region 311 and second semiconductor region 312, thus obtaining an effect of reducing the DCR. The shape of each semiconductor region is not limited to a circle but may be a polygon having the aligned center of gravity.

The dotted lines on the first semiconductor region 311 and the third semiconductor region 313 indicate ranges where the cathode wiring 331A and the third wiring 331C are disposed in a planar view. The shape of the cathode wiring 331A is a circle in a planar view. The inner periphery portion of the third wiring 331C is a surface having a circular hole. At least a part of the third wiring 331C overlaps with the third semiconductor region 313 in a planar view. Although, referring to FIGS. 7A and 7B, each hole disposed on the cathode wiring 331A and the third wiring 331C has a circular inner periphery portion, the wiring shape is not limited thereto but may be, for example, a polygon such as a hexagon or an octagon. Although, referring to FIGS. 7A and 7B, the third wiring 331C and the third semiconductor region 313 have almost the same size, the planar shape of the third wiring 331C is not limited thereto.

An avalanche multiplication region is formed in the depth direction between the first semiconductor region 311 and the second semiconductor region 312. An electric field relief region is disposed so as to surround this avalanche multiplication region.

The electric field relief region only needs to cover a part of the circumference of the avalanche multiplication region, not the entire circumference of the avalanche multiplication region. The boundary between the anode wiring 331B and the insulation film facing the cathode wiring 331A overlaps with the electric field relief region in a planar view. Alternatively, it can be said that the virtual line 332C equally dividing between the cathode wiring outer periphery portion 332A and the anode wiring inner periphery portion 332B overlaps with the electric field relief region.

Referring to FIG. 7A, the ninth semiconductor region 319 is formed only in the cross-section in the A-A′ direction (in the diagonal direction of a pixel) but not formed in the B-B′ direction (in the opposite side direction of a pixel). Referring to the cross-section in the B-B′ direction, the ninth semiconductor region 319 is not formed but the seventh semiconductor region 317 extends to the surface facing the light incidence surface side.

Referring to FIG. 7B, the concavo-convex structure 325 is formed in a lattice form in a planar view. The concavo-convex structure 325 is formed to be overlapped with the first semiconductor region 311 and the fifth semiconductor region 315. The center of gravity of the concavo-convex structure 325 is contained in the avalanche multiplication region in a planar view. With the lattice-formed trench structure as illustrated in FIG. 7B, the trench depth at a trench intersection is larger than the trench depth at a portion where the trench extends alone. However, the trench bottom at a trench intersection exists at a position closer to the light incidence surface side than the half of the thickness of the semiconductor layer. The trench depth refers to the distance from the second surface to the bottom, and also refers to the depth of the concave portion of the concavo-convex structure 325.

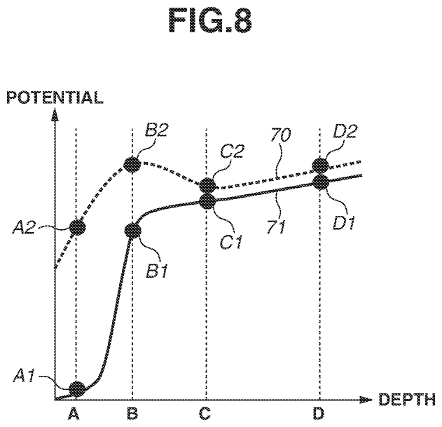

FIG. 8 illustrates a potential chart of the photoelectric conversion element 102 illustrated in FIG. 6.

Referring to FIG. 8, the dotted line 70 denotes the potential distribution along the F-F′ line in FIG. 6, and the solid line 71 in FIG. 8 denotes the potential distribution along the E-E′ line in FIG. 6. FIG. 8 illustrates the potential viewed from electrons as the main carrier electric charges of the N-type semiconductor region. When the main carrier electric charges are holes, the relation between the potential height and the depth is reversed. Also, a depth A (first depth) in FIG. 8 is equivalent to a height A in FIG. 6. Likewise, a depth B (third depth), a depth C, and a depth D (second depth) in FIG. 8 are equivalent to heights B, C, and D in FIG. 6, respectively.

Referring to FIG. 8, the depth A corresponds to a potential height A1 on the solid line 71 and corresponds to a potential height A2 on the dotted line 70. The depth B corresponds to a potential height B1 on the solid line 71 and corresponds to a potential height B2 on the dotted line 70. The depth C corresponds to a potential height C1 on the solid line 71 and corresponds to a potential height C2 on the dotted line 70. The depth D corresponds to a potential height D1 on the solid line 71 and corresponds to a potential height D2 on the dotted line 70.

Referring to FIGS. 6 and 8, the potential height of the first semiconductor region 311 is equivalent to A1, and the potential height in the vicinity of the center of the second semiconductor region 312 is equivalent to B1. The potential height of the fifth semiconductor region 315 is equivalent to C1, and the potential height of the outer periphery of the second semiconductor region 312 is equivalent to B2.

Referring to the dotted line 70 in FIG. 8, the potential gradually decreases from the depth D to the depth C. Then, the potential gradually rises from the depth C to the depth B and then reaches the level B2 at the depth B. Further, the potential decreases from the depth B to the depth A and then falls to the level A2 at the depth A.

On the other hand, referring to the solid line 71, the potential gradually decreases from the depth D to the depth C and from the depth C to the depth B and then falls to the level B1 at the depth B. Then, the potential steeply decreases from the depth B to the depth A and then falls to the level A1 at the depth A. At the depth D, the dotted line 70 and the solid line 71 reach almost the same potential height, and provide a potential gradient that gently decreases toward the second surface side of the semiconductor layer 301 in the regions indicated by the E-E′ and F-F lines. Therefore, electric charges generated in an optical detection apparatus move into the second surface side by the gentle potential gradient.

In the avalanche diode according to the present exemplary embodiment, the P-type second semiconductor region 312 provides a lower impurity density than the N-type first semiconductor region 311, and the N-type first semiconductor region 311 and the P-type second semiconductor region 312 are supplied with such potentials that provide reverse biases. Accordingly, a depletion region is formed toward the side of the second semiconductor region 312. In this structure, the second semiconductor region 312 serves as a potential barrier against electric charges generated through the photoelectric conversion in the fourth semiconductor region 314, making it easier for electric charges to be collected in the first semiconductor region 311.

Although the second semiconductor region 312 is formed in the entire range of the photoelectric conversion element 102 in FIG. 6, an N-type semiconductor region, instead of the second semiconductor region 312 as a P-type semiconductor region, may be provided at the portion overlapping with the first semiconductor region 311 in a planar view. In this example case, the impurity density of this N-type semiconductor region is set to be lower than the impurity density of the first semiconductor region 311. When an N-type semiconductor layer is used, the second semiconductor region 312 is not disposed at the portion overlapping with the first semiconductor region 311 in a planar view. In this case, it can be recognized that the fourth semiconductor region 314 having a slit is formed. In this case, the potential difference between the second semiconductor region 312 and the slit lowers the potential in the direction from the F-F line to the E-E′ line at the depth C in FIG. 6. This enables electric charges to easily move toward the first semiconductor region 311 in the moving process of electric charges generated through the photoelectric conversion in the fourth semiconductor region 314. On the other hand, in a case where the second semiconductor region 312 is formed in the entire range of the photoelectric conversion element 102 as illustrated in FIG. 6, the applied voltage for obtaining an intense electric field required for the avalanche multiplication can be lowered in comparison with a case where a slit is formed. This enables restraining noise due to the formation of a local region having an intense electric field.

Electric charges that has moved to the vicinity of the second semiconductor region 312 are accelerated by a steep potential gradient, i.e., an intense electric field, ranging from the depth B to the depth A along the solid line 71 in FIG. 8. Thus, the electric charges are subjected to the avalanche multiplication.

On the other hand, in the region between the fifth semiconductor region 315 and the P-type second semiconductor region 312 in FIG. 6, i.e., in the range from the depth B to the depth A along the dotted line 70 in FIG. 8, the potential distribution is such that the avalanche multiplication does not take place. Therefore, electric charges generated in the fourth semiconductor region 314 can be counted as signal electric charges without increasing the area of the intense electric field region (avalanche multiplication region) with respect to the size of the photodiode. The descriptions above have been made on the premise that the conductivity type of the fifth semiconductor region 315 is of the N-type, the fifth semiconductor region 315 may be of the P-type as long as the density satisfies the above-described potential relation.

Electric charges generated through the photoelectric conversion in the second semiconductor region 312 flow into the fourth semiconductor region 314 by the potential gradient ranging from the depth B to the depth C along the dotted line 70 in FIG. 8. This structure enables the electric charges in the fourth semiconductor region 314 to easily move into the second semiconductor region 312 for the above-described reasons. Therefore, the electric charges generated through the photoelectric conversion in the second semiconductor region 312 move into the first semiconductor region 311 and are detected as signal electric charges through the avalanche multiplication. Therefore, this structure is provided with the sensitivity for the electric charges generated through the photoelectric conversion in the second semiconductor region 312.

The dotted line 70 in FIG. 8 indicates the cross-sectional potential taken along the F-F line in FIG. 6. Referring to the dotted line 70, A2 denotes the intersection of the height A and the F-F line in FIG. 6, B2 denotes the intersection of the height B and the F-F′ line in FIG. 6, C2 denotes the intersection of the height C and the F-F′ line in FIG. 6, and D2 denotes the intersection of the height D and the F-F′ line in FIG. 6. Electrons generated through the photoelectric conversion in the fourth semiconductor region 314 in FIG. 6 move along the potential gradient from the potential D2 to the potential C2 in FIG. 8. Since the range from the potential C2 to the potential B2 serves as a potential barrier against the electrons, the electrons cannot pass through the range. Therefore, the electrons move into the vicinity of the center of the fourth semiconductor region 314 in FIG. 6 indicated by the E-E′ line. The electrons that has moved further move from the potential gradient C1 to the potential gradient B1 in FIG. 8 and are subjected to the avalanche multiplication along the steep potential gradient from the potential B1 to the potential A1. Then, the electrons pass through the first semiconductor region 311 and then are detected as signal electric charges.

The electric charges generated in the vicinity of the boundary between the third semiconductor region 313 and the sixth semiconductor region 316 in FIG. 6 move along the potential gradient from the potential B2 to the potential C2 in FIG. 8. Then, as described above, the electric charges move to the vicinity of the center of the fourth semiconductor region 314 in FIG. 6 indicated by the E-E′ line. Then, the electric charges are subjected to the avalanche multiplication along the steep potential gradient from the potential B1 to the potential A1.

Then, the electric charges that have been subjected to the avalanche multiplication pass through the first semiconductor region 311 and then are detected as signal electric charges.

Since an intense electric field is applied around the first semiconductor region 311, imbalance occurs in the thermal condition of the sensor substrate and the carrier, resulting in a hot carrier. The hot carrier is trapped by a trap site around the cathode region close to the wiring layer. Since the hot carrier to be trapped increases with time, the potential in the vicinity of the cathode region and the electric field intensity of the intense electric field region also changes over time, resulting in a concern that the breakdown voltage changes over time.

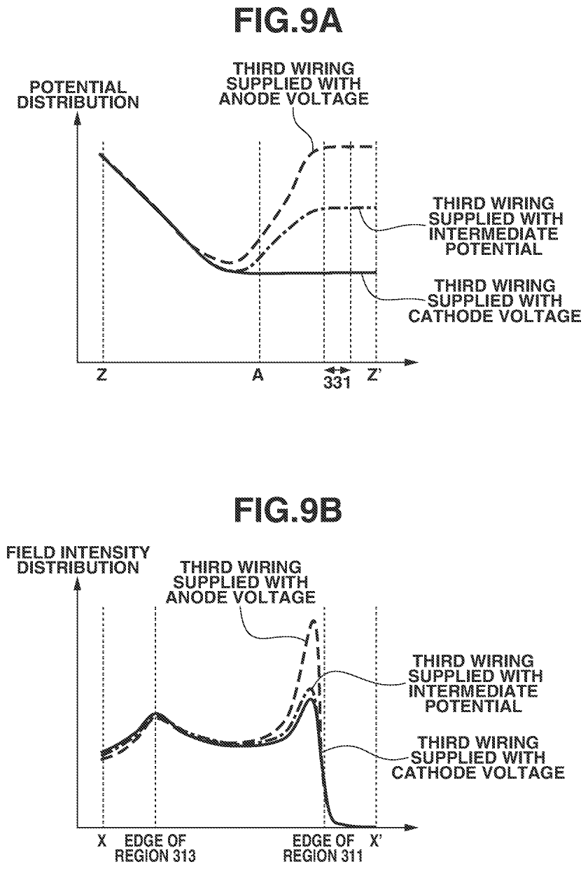

FIG. 9A is a schematic view illustrating the potential distribution on the Z-Z′ cross section in FIG. 6. FIG. 9B is a schematic view illustrating the electric field intensity distribution on the X-X′ cross section in FIG. 6. Referring to FIGS. 9A and 9B, a solid line indicates a case where the third wiring 331C is not disposed, a dot-dash line indicates a case where the third wiring 331C is supplied with an intermediate potential that is higher than the anode potential and lower than the cathode potential, and a broken line indicates a case where the third wiring 331C is supplied with the anode potential.

To restrain the breakdown voltage variation over time, it is desirable that the potential at height A is higher than the minimum potential between the height A and the height Z on the Z-Z′ cross section in the third semiconductor region 313. More specifically, it is desirable that a potential barrier is formed at the height A with respect to the height, where the potential is minimized, between the height A and the height Z. The potential difference between the minimum potential from the height A to the height Z and the potential at the height A is referred to as a potential barrier ΔV.

As illustrated in FIG. 9A, the above-described potential arrangement is easier to be satisfied when the third wiring 331C is supplied with a lower voltage. On the other hand, as illustrated in FIG. 9B, the concentration of the electric field on the edge of the first semiconductor region 311 is more induced when the third wiring 331C is supplied with a lower voltage. When the electric field concentrates on the edge of the first semiconductor region 311, the dark current increases to increase the DCR. Therefore, when the anode potential is supplied to the third wiring 331C, the increase of the DCR can be an issue. It is desirable that the voltage to be supplied to the third wiring 331C is higher than the anode potential.

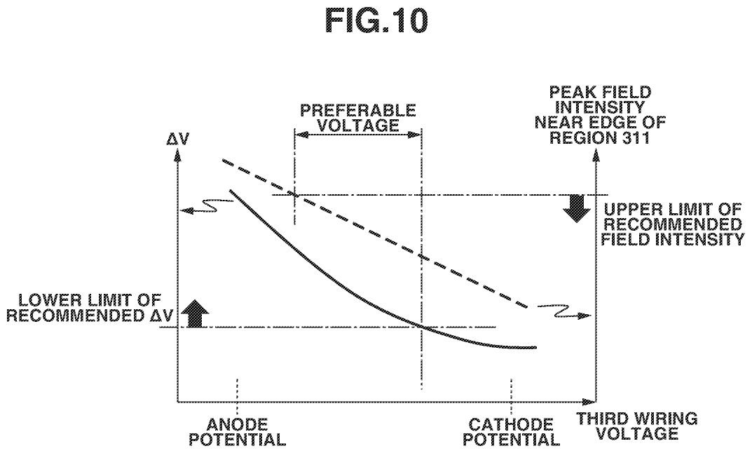

A preferred voltage setting on the third wiring 331C will be more specifically described below with reference to FIG. 10.

FIG. 10 is a conceptual view illustrating a relation between the potential barrier ΔV formed at the height A (assigned to the first vertical axis), the peak electric field intensity in the vicinity of the edge of the first semiconductor region 311 (assigned to the second vertical axis), and the voltage to be supplied to the third wiring 331C.

As described above with reference to FIGS. 9A and 9B, decreasing the voltage supplied to the third wiring 331C increases the potential barrier ΔV and also increases the peak electric field intensity in the vicinity of the edge of the first semiconductor region 311.

FIG. 10 illustrates the lower limit of the potential barrier ΔV recommended to restrain the breakdown voltage variation over time, and the upper limit of the peak electric field intensity in the vicinity of the edge of the first semiconductor region 311 recommended to restrain the increase of the DCR. The voltage that satisfies the recommended value of the potential barrier ΔV and the peak electric field intensity in the vicinity of the edge of the first semiconductor region 311 is a preferred voltage setting value of the third wiring. For example, it is desirable that the potential barrier ΔV is 200 mV or higher and that the peak electric field intensity in the vicinity of the edge of the first semiconductor region 311 is 300 kV/cm or lower. These values are not necessarily limited thereto depending on the element structure.

For example, the anode voltage is around −30 V and the cathode voltage is around 1V at a height of about 0.1 μm from the boundary surface of the semiconductor layer of the third wiring 331C. In this case, the range from −10 V to −20 V is a preferred voltage of the third wiring 331C according to the recommended values in FIG. 10.

When the voltage supplied to the third wiring 331C becomes higher than the voltage supplied to the cathode wiring, the potential barrier ΔV becomes negative, and a potential gradient in the electron acceleration direction is formed. Therefore, the voltage supplied to the third wiring 331C needs to be lower than Vdd supplied to the cathode wiring or the voltage that can be applied to the cathode wiring, Vdd−Vex, when the SPAD is driven, where Vdd denotes the drain voltage of the metal oxide semiconductor (MOS) transistor on the bottom substrate side, and Vex denotes the excessive excess bias voltage exceeding the breakdown voltage of the SPAD.

The voltage to be supplied to the third wiring 331C may be set to a ground (GNR) voltage that is lower than Vdd. The GND potential refers to the reference potential of the pixel circuit, for example, the ground potential. In this case, the PAD for externally supplying a voltage to the sensor is not required, achieving a simplified design and a reduced area of the entire chip.

The voltage to be supplied to the third wiring 331C, Vmid, may be Vmid=(Van−Vca)/2 that minimizes the voltage differences from the cathode voltage Vca and the anode voltage Van. The above-described value is most suitable to ensure the withstand voltage of the third wiring 331C. However, the voltage difference between wires can be sufficiently reduced within a range {(Van−Vca)/2}*0.8≤Vmid≤{(Van−Vca)/2}*1.2. This enables improving the degree of freedom of the wiring layout since the wiring arrangement is limited by the withstand voltage between wires.

Thus, by supplying a preferred voltage larger than the anode voltage and smaller than the cathode voltage to the third wiring 331C, the breakdown voltage variation over time can be reduced while restraining the DCR. Further, to improve the effect of restraining the breakdown voltage variation over time, it is desirable to minimize the distance between the semiconductor layer and the third wiring 331C in the depth direction. More specifically, the third wiring 331C needs to be disposed in a layer as close to the semiconductor layer as possible, or desirably disposed in the layer closest thereto out of a plurality of wiring layers. The plurality of wiring layers refers to the wiring layers disposed above the upper surface of the contact plug that connects the anode wiring 331B and the first semiconductor region 311. More specifically, in the direction perpendicular to the in-plane direction of the second surface of the semiconductor layer, the distance between the wiring layer configuring a plurality of wiring layers and the second surface is longer than the distance between the portion farthest from the second surface of the contact plug (upper surface of the contact plug) and the second surface of the semiconductor layer.

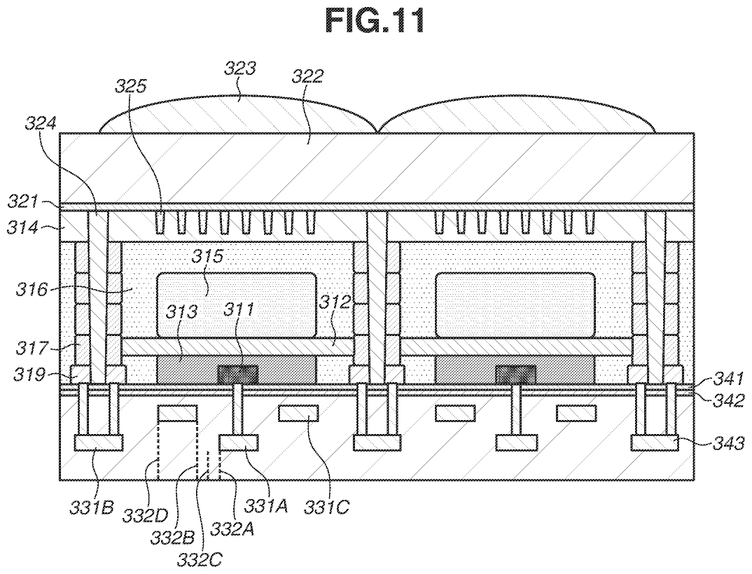

A photoelectric conversion apparatus according to a second exemplary embodiment will be described below with reference to FIG. 11.

Descriptions duplicated with the first exemplary embodiment will be omitted, and portions different from those of the first exemplary embodiment will be mainly described below. According to the second exemplary embodiment, the cathode wiring 331A, the anode wiring 331B, and the third wiring 331C are formed at different heights with respect to the semiconductor layer.

FIG. 11 is a cross-sectional view illustrating two adjacent pixels of the photoelectric conversion element 102 of the photoelectric conversion apparatus according to the second exemplary embodiment, taken along a direction perpendicular to the planar direction of the substrate.

According to the first exemplary embodiment, the cathode wiring 331A, the anode wiring 331B, and the third wiring 331C are formed in the same wiring layer. According to the present exemplary embodiment, the cathode wiring 331A, the anode wiring 331B, and the third wiring 331C are formed at different positions with respect to the semiconductor layer in the depth direction. This makes it easier to ensure a distance between the cathode wiring 331A, the anode wiring 331B, and the third wiring 331C, increasing the degree of freedom of the wiring layout.

Disposing the third wiring 331C at a position closer to the front surface of the semiconductor layer than the cathode wiring 331A and the anode wiring 331B increases the contribution of the voltage of the third wiring 331C to the potential and the electric field inside the semiconductor layer. Therefore, the range of the preferred voltage setting illustrated in FIG. 10 shifts to the right. This enables the GND voltage to be included in preferred voltage conditions, as a voltage to be applied to the third wiring 331C.

This further decreases the voltage difference between the cathode voltage and the voltage to be applied to the third wiring 331C. The third wiring 331C is closer to the cathode wiring than the anode wiring on the planar layout. Therefore, reducing the voltage difference between the voltage to be applied to the third wiring 331C and the cathode voltage enables increasing the degree of freedom of the wiring layout.

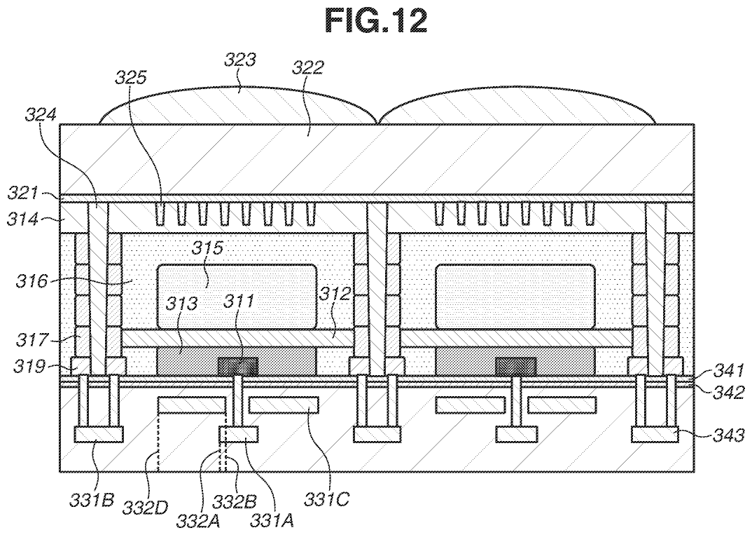

A photoelectric conversion apparatus according to a third exemplary embodiment will be described below with reference to FIG. 12.

Descriptions duplicated with the first and second exemplary embodiments will be omitted, and portions different from the first exemplary embodiment will be mainly described below. According to the third exemplary embodiment, the third wiring 331C overlaps with the cathode wiring on a plane.

FIG. 12 is a cross-sectional view illustrating two adjacent pixels of the photoelectric conversion element 102 of the photoelectric conversion apparatus according to the present modification, taken along a direction perpendicular to the planar direction of the substrate. The third wiring 331C is disposed in the wiring layer closer to the front surface of the semiconductor layer than the cathode wiring 331A and the anode wiring 331B, and overlaps with the cathode wiring 331A in a planar view.

This configuration enables utilizing the third wiring 331C as a light-reflective structure. Part of the light incident from the rear surface of the substrate passes through the semiconductor layer and transmits to the front surface side of the substrate. An effect of sensitivity improvement can be obtained when the light is effectively reflected by the third wiring 331C.

According to the first exemplary embodiment, part of the light that has penetrated the substrate can be reflected. However, according to the first exemplary embodiment, since the third wiring 331C is disposed at the same height as the anode wiring 331B and the cathode wiring 331A, the position enabling wire arrangement is limited from the viewpoint of the withstand voltage. On the other hand, the configuration according to the present exemplary embodiment enables the third wiring 331C to cover a larger area and therefore reflect light at a position closer to the semiconductor layer. This configuration returns a larger amount of light to the pixels, making it possible to obtain an effect of higher sensitivity improvement.

Further sensitivity improvement can be expected by overlapping the third wiring 331C with the anode wiring 331B in a planar view.

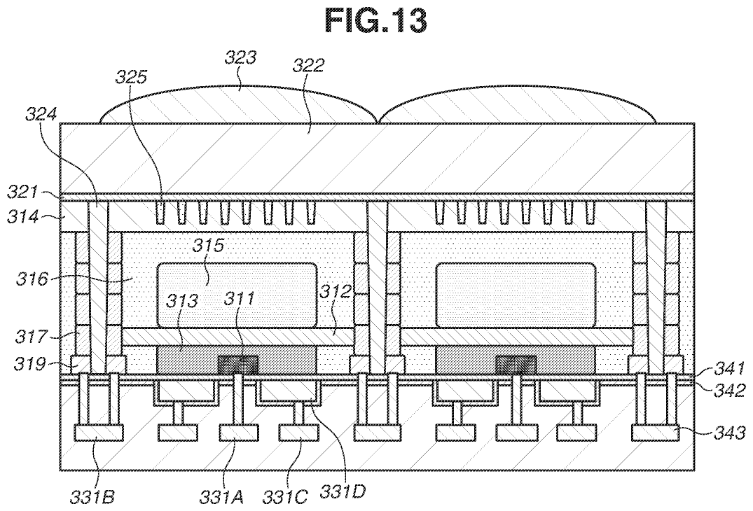

A fourth exemplary embodiment will be described below with reference to FIG. 13.

According to the fourth exemplary embodiment, there is provided an extension portion (fourth wiring) 331D of the third wiring 331C, connected to the third wiring 331C. The material of the fourth wiring 331D may be polysilicon or a metal such as tungsten. FIG. 13 illustrates an example of the fourth wiring 331D made of polysilicon. The fourth wiring 331D is disposed between the oxide film 341 and the protection film 342.

This configuration enables directly arranging wires on the semiconductor layer, resulting in a shorter distance between the semiconductor layer and the fourth wiring 331D in the depth direction than in the above-described exemplary embodiments. The configuration enables effectively applying the voltage supplied to the third wiring 331C to the semiconductor layer, making it possible to improve the effect of restraining the breakdown voltage variation over time. The configuration enables obtaining the effect of restraining the breakdown voltage variation over time by supplying a smaller voltage, thus reducing the restrictions on the wiring layout due to the withstand voltage of the wiring.

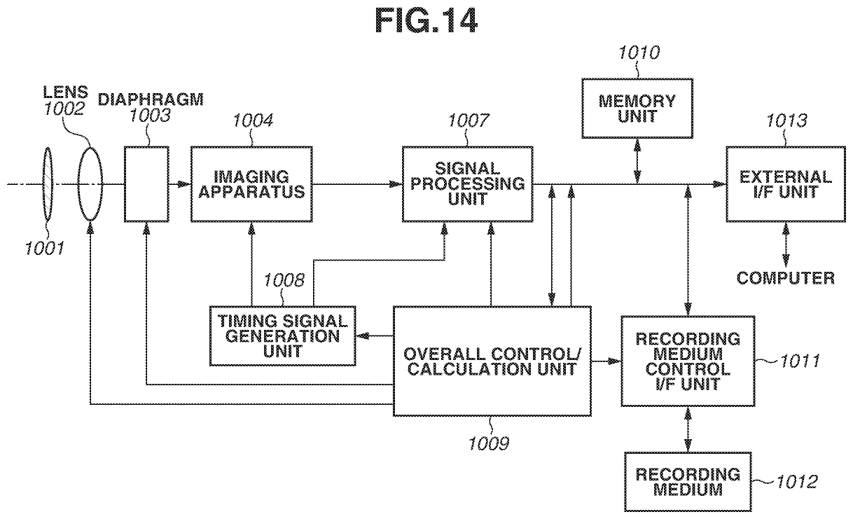

A photoelectric conversion system according to a fifth exemplary embodiment will be described below with reference to FIG. 14. FIG. 14 is a block diagram illustrating an overall configuration of the photoelectric conversion system according to the fifth exemplary embodiment.

The photoelectric conversion apparatuses 100 according to the first to fourth exemplary embodiments are applicable to various types of photoelectric conversion systems. Examples of applicable photoelectric conversion systems include digital still cameras, digital camcorders, monitoring cameras, copying machines, facsimiles, portable telephones, on-vehicle cameras, and observation satellites. A camera module including an optical system such as a lens and an imaging apparatus is also included in the photoelectric conversion system. FIG. 14 is a block diagram illustrating a digital still camera as an example of a photoelectric conversion system.

The example of a photoelectric conversion system illustrated in FIG. 14 includes an imaging apparatus 1004 as an example of a photoelectric conversion apparatus 100, and a lens 1002 that forms an optical image of a subject on an imaging apparatus 1004. The photoelectric conversion system further includes a diaphragm 1003 that changes the light quantity passing through the lens 1002, and a barrier 1001 that protects the lens 1002. The lens 1002 and the diaphragm 1003 configure an optical system that condenses light to the imaging apparatus 1004. The imaging apparatus 1004, a photoelectric conversion apparatus 100 according to any one of the above-described exemplary embodiments, converts the optical image formed by the lens 1002 into an electrical signal.

The photoelectric conversion system includes a signal processing unit 1007 as an image generation unit that generates an image by processing the output signal output from the imaging apparatus 1004. The signal processing unit 1007 performs various kinds of correction and compression as required and outputs image data. The signal processing unit 1007 may be formed on a semiconductor substrate provided with the imaging apparatus 1004 thereon, or on a semiconductor substrate different from the substrate of the imaging apparatus 1004.

The photoelectric conversion system further includes a memory unit 1010 that temporarily stores image data, and an external interface (I/F) unit 1013 that communicates with an external computer. The photoelectric conversion system further includes a recording medium 1012, such as a semiconductor memory, used to record and read imaging data, and a recording medium control I/F unit 1011 used to record and read imaging data to/from the recording medium 1012. The recording medium 1012 may be built in the photoelectric conversion system, or may be attachable to and detachable from the photoelectric conversion system.

The photoelectric conversion system further includes an overall control/calculation unit 1009 that performs various calculations and controls the entire digital still camera, and a timing generation unit 1008 that outputs various timing signals to the imaging apparatus 1004 and the signal processing unit 1007. The timing signals may be input from the outside. The photoelectric conversion system needs to include at least the imaging apparatus 1004 and the signal processing unit 1007 that processes the output signal output from the imaging apparatus 1004.

The imaging apparatus 1004 outputs an image capture signal to the signal processing unit 1007. The signal processing unit 1007 subjects the image capture signal output from the imaging apparatus 1004 to predetermined signal processing and outputs image data. The signal processing unit 1007 generates an image by using the image capture signal.

The present exemplary embodiment makes it possible to implement a photoelectric conversion system to which the photoelectric conversion apparatus 100 (imaging apparatus) according to any one of the above-described exemplary embodiments is applied.

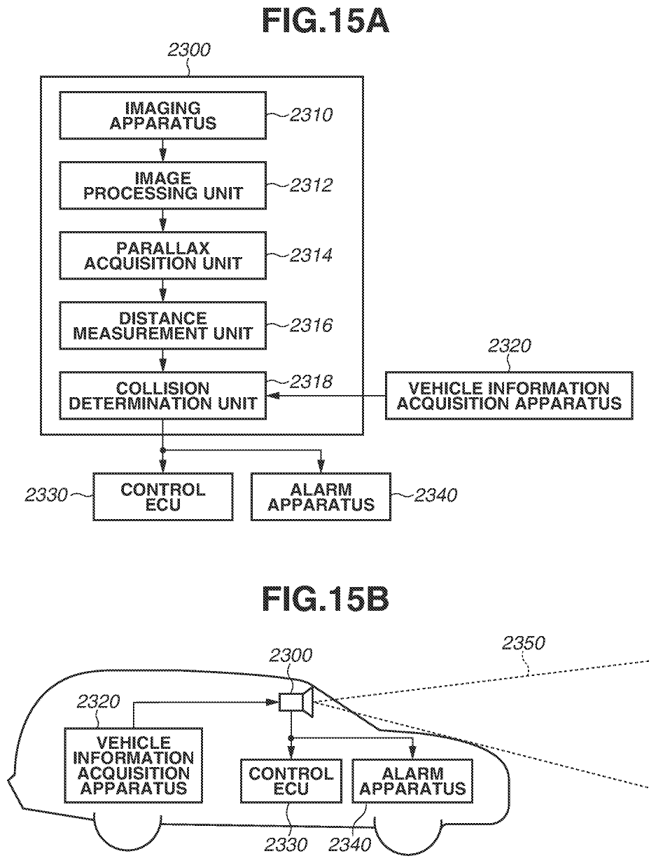

A photoelectric conversion system and a moving body according to a sixth exemplary embodiment will be described below with reference to FIGS. 15A and 15B, respectively. FIGS. 15A and 15B illustrate configurations of the photoelectric conversion system and the moving body, respectively, according to the sixth exemplary embodiment.

FIG. 15A illustrates an example of a photoelectric conversion system related to an on-vehicle camera. A photoelectric conversion system 2300 includes an imaging apparatus 2310. The imaging apparatus 2310 is the photoelectric conversion apparatus 100 (imaging apparatus) according to any one of the above-described exemplary embodiments. The photoelectric conversion system 2300 includes an image processing unit 2312 that performs image processing on a plurality of pieces of image data acquired by the imaging apparatus 2310, and a parallax acquisition unit 2314 that calculates a parallax (phase difference between parallax images) based on the plurality of pieces of image data acquired by the photoelectric conversion system 2300. The photoelectric conversion system 2300 further includes a distance acquisition unit 2316 that calculates the distance to a target object based on the calculated parallax, and a collision determination unit 2318 that determines the possibility of collision based on the calculated distance. The parallax acquisition unit 2314 and the distance acquisition unit 2316 are examples of distance information acquisition units for acquiring information about the distance to the target object. More specifically, the distance information includes information about the parallax, the defocus amount, and the distance to the target object. The collision determination unit 2318 may determine the possibility of collision by using one of these pieces of distance information. The distance information acquisition units may be implemented by specially designed hardware components or implemented by software modules.

The distance information acquisition units may also be implemented by a Field Programmable Gate Array (FPGA), an Application Specific Integrated Circuit (ASIC), or a combination of both.

The photoelectric conversion system 2300 is connected with a vehicle information acquisition apparatus 2320 to acquire vehicle information such as the vehicle speed, yaw rate, and steering angle. The photoelectric conversion system 2300 is connected with a control Electronic Control Unit (ECU) 2330 as a control apparatus that outputs control signals for generating a braking force on a vehicle based on the determination result by the collision determination unit 2318. The photoelectric conversion system 2300 is also connected with an alarm apparatus 2340 that generates an alarm to the driver based on the determination result by the collision determination unit 2318. For example, if the possibility of collision is high based on a determination result by the collision determination unit 2318, the control ECU 2330 performs vehicle control to avoid a collision and reduce damages, for example, by applying brakes, releasing the accelerator, or restraining the engine power. The alarm apparatus 2340 warns the driver by generating an alarm sound, displaying alarm information on the screen of the car navigation system, or applying a vibration to the seat belt or steering wheel.

According to the present exemplary embodiment, the photoelectric conversion system 2300 captures images of the surrounding of the vehicle, for example, images ahead of or behind the vehicle. FIG. 15B illustrates a photoelectric conversion system that captures images ahead of the vehicle (an imaging range 2350). The vehicle information acquisition apparatus 2320 transmits an instruction to the photoelectric conversion system 2300 or the imaging apparatus 2310. The above-described configuration enables improving the accuracy of distance measurement.

Although the present exemplary embodiment has been described above centering on control for avoiding a collision with other vehicles, the present exemplary embodiment is also applicable to automatic driving control for following another vehicle and automatic driving control for retaining the vehicle within the lane. The photoelectric conversion system is applicable not only to vehicles such as automobiles but also to moving bodies (moving apparatuses) such as vessels, airplanes, and industrial robots. In addition, the photoelectric conversion system is applicable not only to moving bodies but also to intelligent transport systems (ITS's) and a wide range of apparatuses utilizing object recognition.

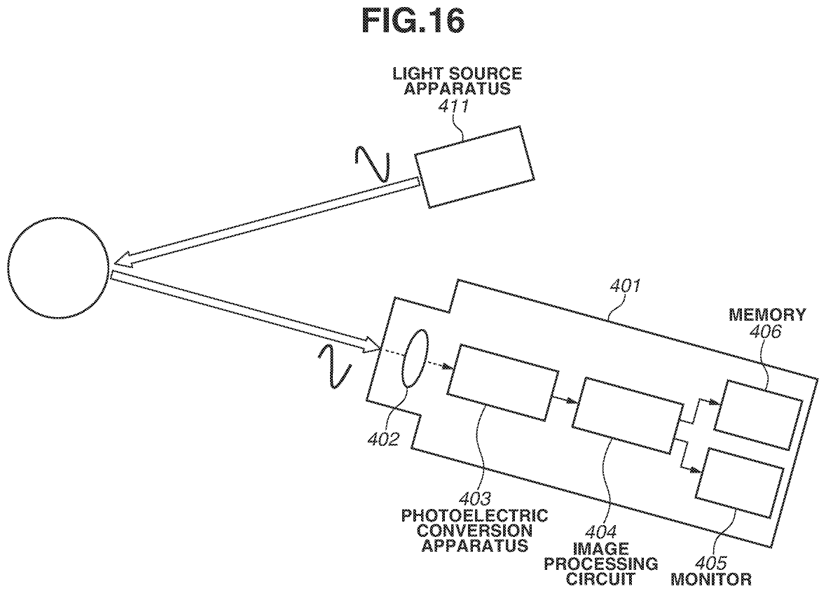

A photoelectric conversion system according to a seventh exemplary embodiment will be described below with reference to FIG. 16. FIG. 16 is a block diagram illustrates an example configuration of a distance image sensor as the photoelectric conversion system according to the seventh exemplary embodiment.

As illustrated in FIG. 16, a distance image sensor 401 includes an optical system 402, a photoelectric conversion apparatus 403, an image processing circuit 404, a monitor 405, and a memory 406. A light source apparatus 411 emits light toward a subject. The distance image sensor 401 receives light (modulated light or pulsed light) reflected by the surface of the subject to acquire a distance image according to the distance to the subject.

The optical system 402 including one or a plurality of lenses guides the image light (incident light) from the subject to the photoelectric conversion apparatus 403 to form an image on the light-receiving surface (sensor unit) of the photoelectric conversion apparatus 403.

The photoelectric conversion apparatus 100 according to each of the above-described exemplary embodiments is applied to the photoelectric conversion apparatus 403. The image processing circuit 404 is supplied with a distance signal indicating the distance acquired from a light receiving signal output from the photoelectric conversion apparatus 403.

The image processing circuit 404 performs image processing for distance image configuration based on the distance signal supplied from the photoelectric conversion apparatus 403. The distance image (image data) obtained by the image processing is supplied to the monitor 405 for display and to the memory 406 for storage (recording).

The distance image sensor 401 configured in this way applies the above-described photoelectric conversion apparatus 403 to enable acquiring, for example, a more accurate distance image with the improvement of the pixel characteristics.

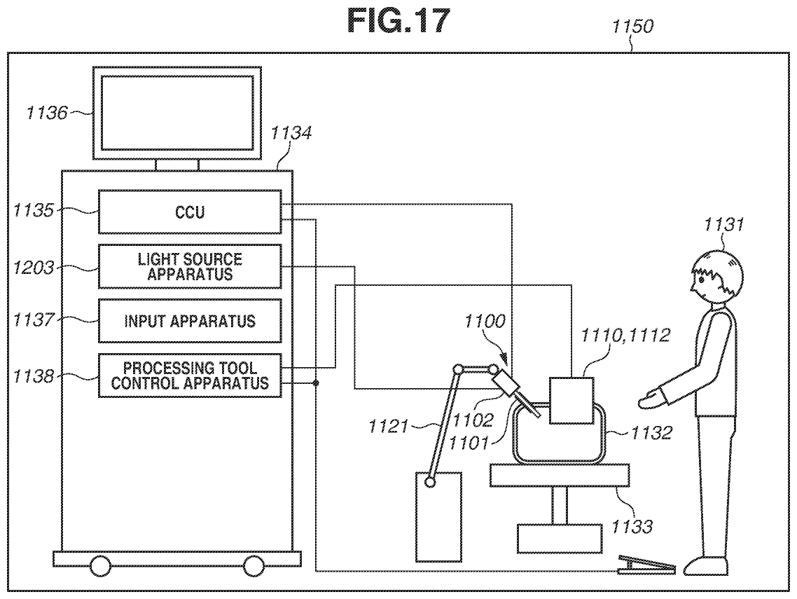

A photoelectric conversion system according to an eighth exemplary embodiment will be described below with reference to FIG. 17. FIG. 17 is a schematic view illustrating an example configuration of an endoscopic surgery system as the photoelectric conversion system according to the eighth exemplary embodiment.

Referring to FIG. 17, an operator (doctor) 1131 operates on a patient 1132 on a patient bed 1133 by using an endoscopic surgery system 1150. As illustrated in FIG. 17, the endoscopic surgery system 1150 includes an endoscope 1100, an operation tool 1110, and a cart 1134 that mounts various apparatuses for endoscopic operations.

The endoscope 1100 includes a lens barrel 1101 of which a region of a predetermined length from the tip is to be inserted into the body cavity of the patient 1132, and a camera head 1102 connected to the base end portion of the lens barrel 1101. Referring to the example illustrated in FIG. 17, although the endoscope 1100 is configured as what is called a hard mirror having the hard lens barrel 1101, the endoscope 1100 may be configured as what is called a flexible mirror having a flexible lens barrel 1101.

An opening with a fitted-in object lens is disposed at the tip of the lens barrel 1101. The endoscope 1100 is connected with a light source apparatus 1203. Light generated by the light source apparatus 1203 is guided to the tip of the lens barrel 1101 by a light guide extended inside the lens barrel 1101, and then is radiated toward the object under observation in the body cavity of the patient 1132 via the object lens. The endoscope 1100 may be a direct view mirror, an oblique view mirror, or a side view mirror.

An optical system and a photoelectric conversion apparatus 100 are disposed inside the camera head 1102. Reflected light (observation light) from the object under observation is condensed into the photoelectric conversion apparatus 100 by the optical system. The photoelectric conversion apparatus 100 photoelectrically converts the observation light to generate an electrical signal corresponding to the observation light, i.e., an image signal corresponding to the observation image. As the photoelectric conversion apparatus 100, the photoelectric conversion apparatus 100 according to each of the above-described exemplary embodiments can be used. The image signal is transmitted to a camera control unit (CCU) 1135 as RAW data.

The CCU 1135 configured by a Central Processing Unit (CPU) or a Graphics Processing Unit (GPU) totally controls the operations of the endoscope 1100 and a display apparatus 1136. The CCU 1135 further receives the image signal from the camera head 1102 and subjects the image signal to various kinds of image processing for displaying an image based on the image signal, such as development processing (demosaic processing).

The display apparatus 1136 displays an image based on the image signal having been subjected to the image processing by the CCU 1135 under the control of the CCU 1135.

The light source apparatus 1203 includes, for example, a light source such as a Light Emitting Diode (LED) and supplies irradiation light for capturing an image of the operation portion to the endoscope 1100.

An input apparatus 1137 is an input interface to the endoscopic surgery system 1150. The user can input various kinds of information and instructions to the endoscopic surgery system 1150 via the input apparatus 1137.

A processing tool control apparatus 1138 controls the drive of an energy processing tool 1112 for cautery and incision of tissues and sealing of blood vessels.

The light source apparatus 1203 for supplying irradiation light for capturing an image of the operation portion to the endoscope 1100 can include a white light source including, for example, an LED, a laser light source, or a combination of both. When a white light source is configured by a combination of RGB laser light sources, it is possible to control the output intensity and output timing for each color (each wavelength) with high accuracy and hence to subject a captured image to white balance adjustment by the light source apparatus 1203. In this case, it is also possible to capture an image corresponding to each of RGB on a time-sharing basis by irradiating the object under observation with a laser beam from each of the RGB laser sources on a time-sharing basis, and controlling the drive of the image sensor of the camera head 1102 in synchronization with the irradiation timing. This method enables obtaining a color image even without disposing color filters in the image sensor.

The drive of the light source apparatus 1203 may be controlled to change the intensity of the output light at predetermined time intervals. It is possible to generate an image with a wide dynamic range, free from underexposure and overexposure, by controlling the drive of the image sensor of the camera head 1102 in synchronization with the timing of changing the light intensity to acquire images on a time-sharing basis and then combining the images.

The light source apparatus 1203 may be configured to be able to supply light in a predetermined wavelength band conforming to special light observation. The special light observation utilizes, for example, the wavelength dependence of absorption of light in a body tissue. More specifically, by irradiating the object under observation with narrower-band light than irradiation light used in normal observation (i.e., white light), an image of a predetermined tissue such as blood vessels in the superficial portion of the mucous membrane is captured with high contrast.

Alternatively, in the special light observation, fluorescence observation may be performed to capture an image through fluorescence generated by exciting light irradiation. The fluorescence observation enables irradiating a body tissue with exciting light to observe the fluorescence from the body tissue, or enables locally injecting a reagent such as indocyanine green (ICG) into the body tissue, and irradiating the body tissue with exciting light corresponding to the fluorescence wavelength of the reagent to obtain a fluorescence image. The light source apparatus 1203 can be configured to be able to supply narrow-band light and/or exciting light conforming to such special light observation.

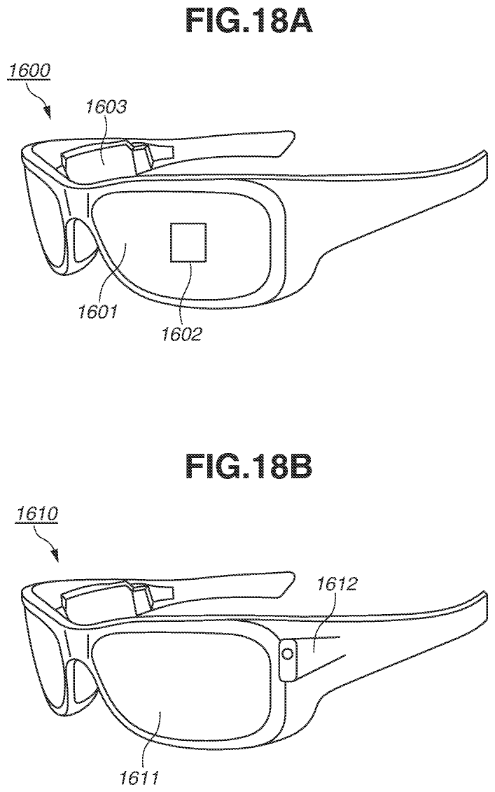

A photoelectric conversion system according to a ninth exemplary embodiment will be described below with reference to FIGS. 18A and 18B. FIG. 18A illustrates glasses 1600 (smart glasses) as the photoelectric conversion system according to the ninth exemplary embodiment. The glasses 1600 include a photoelectric conversion apparatus 1602. The photoelectric conversion apparatus 1602 is the photoelectric conversion apparatus 100 according to each exemplary embodiment. A display apparatus including a light emitting apparatus such as an (organic light emitting diode) OLED or an LED may be disposed on the back surface side of a lens 1601. The glasses 1600 may include one or a plurality of the photoelectric conversion apparatuses 1602, or include a combination of a plurality of types of the photoelectric conversion apparatuses 1602. The arrangement position of the photoelectric conversion apparatus 1602 is not limited to FIG. 18A.

The glasses 1600 further include a control apparatus 1603. The control apparatus 1603 functions as a power source that supplies power to the photoelectric conversion apparatus 1602 and the above-described display apparatus. The control apparatus 1603 controls the operations of the photoelectric conversion apparatus 1602 and the display apparatus. An optical system for condensing light to the photoelectric conversion apparatus 1602 is formed on the lens 1601.

FIG. 18B illustrates glasses 1610 (smart glasses) according to an example application. The glasses 1610 include a control apparatus 1612 that mounts a photoelectric conversion apparatus equivalent to the photoelectric conversion apparatus 1602 and a display apparatus. The photoelectric conversion apparatus 1602 in the control apparatus 1612 and an optical system for projecting light emitted from the display apparatus are formed on a lens 1611 on which an image is projected. The control apparatus 1612 functions as a power source that supplies power to the photoelectric conversion apparatus 1602 and the display apparatus, and controls the operations of the photoelectric conversion apparatus 1602 and the display apparatus. The control apparatus 1612 may include a line-of-sight detection unit that detects the line of sight of the wearer. Infrared radiation may be used for line-of-sight detection. An infrared emission unit emits infrared light to the eyeballs of the user who is gazing at a display image. When an imaging unit having a light receiving element detects reflected light of the emitted infrared light from the eyeballs, a captured image of the eyeballs is obtained. The degradation of the image quality can be reduced by providing a reduction unit for reducing light from the infrared emission unit to a display unit in a planar view.

The user's line-of-sight to the display image is detected based on the captured image of the eyeballs obtained by infrared imaging. An arbitrary known technique is applicable to line-of-sight detection using a captured image of the eyeballs. Examples of applicable techniques include a line-of-sight detection method based on a Purkinje image by the reflection of irradiation light on the cornea.

More specifically, line-of-sight detection processing based on the pupil cornea reflection method is performed. The use of the pupil cornea reflection method detects the user's line-of-sight by calculating a line-of-sight vector representing the orientation (rotational angle) of the eyeballs based on a pupillary image and a Purkinje image included in a captured image of the eyeballs.

The display apparatus according to the present exemplary embodiment may include a photoelectric conversion apparatus 1602 having a light receiving element, and the display image of the display apparatus may be controlled based on line-of-sight information about the user from the photoelectric conversion apparatus 1602.

More specifically, for the display apparatus, a first visual range to be gazed by the user and a second visual range other than the first visual range are determined based on the line-of-sight information. The first and second visual ranges may be determined by the control apparatus of the display apparatus, or received from an external control apparatus that has determined these visual ranges. In the display region of the display apparatus, the display resolution of the first visual range may be controlled to be higher than that of the second visual range. More specifically, the resolution of the second visual range may be lower than that of the first visual range.

The display region includes a first display region and a second display region different from the first display region. The region having a higher priority may be determined from the first and second display regions based on the line-of-sight information. The first and second visual ranges may be determined by the control apparatus of the display apparatus, or received from an external control apparatus that has determined these visual ranges. The resolution of the region having a higher priority may be controlled to be higher than that of the region other than the region having a higher priority. More specifically, the region having a relatively lower priority may have a low resolution.

The first visual range and the region having a higher priority may be determined by using an Artificial Intelligence (AI). The AI may be a model configured to estimate the angle of the line of sight and the distance to the target objective on the line of sight based on an image of the eyeballs by using the image of the eyeballs and the direction in which the eyeballs in the image actually watch, as teacher data. An AI program may be held by the display apparatus, the photoelectric conversion apparatus 1602, or an external apparatus. When the AI program is held by the external apparatus, the AI program is transmitted to the display apparatus through communication.

When performing display control based on visual recognition detection, the present disclosure is preferably applicable to smart glasses further including a photoelectric conversion apparatus 1602 that captures an image of the outside. The smart glasses can display captured external information in real time.

### (Modifications)

The present disclosure is not limited to the above-described exemplary embodiments but can be modified in diverse ways.

For example, the exemplary embodiments of the present disclosure also include an example case where a part of the configuration of any one exemplary embodiment is appended to another exemplary embodiment, and an example case where a part of the configuration of any one exemplary embodiment is replaced with a part of the configuration of another exemplary embodiment.

The photoelectric conversion systems according to the fifth and sixth exemplary embodiments are examples of photoelectric conversion systems to which the photoelectric conversion apparatus of the present disclosure is applicable. Photoelectric conversion systems to which the photoelectric conversion apparatus of the present disclosure is applicable is not limited to the configurations illustrated in FIGS. 14 to 15B. This also applies to the ToF system according to the seventh exemplary embodiment, the endoscope according to the eighth exemplary embodiment, and the smart glasses according to the ninth exemplary embodiment.

The above-described exemplary embodiments are to be considered as illustrative in embodying the present disclosure, and are not to be interpreted as restrictive on the technical scope of the present disclosure. More specifically, the present disclosure may be embodied in diverse forms without departing from the technical concepts or essential characteristics thereof.

The present disclosure makes it possible to reduce the breakdown voltage variation over time by the injection of hot carriers into the semiconductor substrate boundary surface restraining the DCR.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-000315, filed Jan. 5, 2022, which is hereby incorporated by reference herein in its entirety.

What is claimed is:

1. A photoelectric conversion apparatus comprising an avalanche diode disposed in a semiconductor layer having a first surface and a second surface facing the first surface,
wherein the avalanche diode includes:
a first semiconductor region of a first conductivity type disposed at a first depth;
a second semiconductor region of a second conductivity type disposed at a second depth deeper from the second surface than the first depth;
a third semiconductor region disposed at an edge of the first semiconductor region in a planar view;
a first wiring connected to the first semiconductor region;
a second wiring connected to the second semiconductor region; and
a third wiring not connected to the semiconductor layer, at least a part of the third wiring overlapping with the third semiconductor region in a planar view, and
wherein a third voltage to be supplied to the third wiring is a value between a first voltage to be supplied to the first wiring and a second voltage to be supplied to the second wiring.

2. The photoelectric conversion apparatus according to claim 1, wherein an impurity density in the third semiconductor region is lower than an impurity density in the first semiconductor region.

3. The photoelectric conversion apparatus according to claim 1,
wherein the first and third wirings are formed in a plurality of wiring layers stacked in layers on a side of the second surface, and
wherein the third wiring is formed in a wiring layer that is further from the second surface than a contact connecting the first semiconductor region and the first wiring, and is closer to the second surface than the first wiring.

4. The photoelectric conversion apparatus according to claim 3, wherein at least a part of the first wiring overlaps with at least a part of the third wiring in a planar view.

5. The photoelectric conversion apparatus according to claim 1,
wherein the second and third wirings are formed in a plurality of wiring layers stacked in layers on a side of the second surface, and
wherein the third wiring is formed in a wiring layer that is further from the second surface a contact connecting the second semiconductor region and the second wiring, and is closer to the second surface than the second wiring.

6. The photoelectric conversion apparatus according to claim 5, wherein at least a part of the second wiring overlaps with at least a part of the third wiring in a planar view.

7. The photoelectric conversion apparatus according to claim 1, wherein at least a part of the third wiring is made of polysilicon.

8. The photoelectric conversion apparatus according to claim 1,
wherein the third wiring is formed in a plurality of wiring layers stacked in layers on a side of the second surface, and
wherein the third wiring is formed in a wiring layer that is further from the second surface than a contact connecting the first semiconductor region and the first wiring, and is closest to the second surface out of the plurality of wiring layers.

9. The photoelectric conversion apparatus according to claim 1, wherein the first and second wirings are formed in the same wiring layer stacked on a side of the second surface.

10. The photoelectric conversion apparatus according to claim 1, wherein the third voltage is within a range {(Van−Vca)/2}*0.8≤Vmid≤{(Van−Vca)/2}*1.2 where Vca denotes the first voltage, Van denotes the second voltage, and Vmid denotes the third voltage.

11. The photoelectric conversion apparatus according to claim 1, wherein the third voltage is a ground voltage.

12. The photoelectric conversion apparatus according to claim 1, further comprising a fourth semiconductor region of the second conductivity type disposed at a third depth deeper from the second surface than the second depth.

13. The photoelectric conversion apparatus according to claim 12,
wherein a fifth semiconductor region of the first conductivity type is disposed between the second and fourth semiconductor regions, and
wherein an impurity density of the first conductivity type in the fifth semiconductor region is lower than an impurity density of the first conductivity type in the first semiconductor region.

14. The photoelectric conversion apparatus according to claim 13, wherein a potential difference between the first and second semiconductor regions is larger than a potential difference between the second and fifth semiconductor regions.

15. The photoelectric conversion apparatus according to claim 1, wherein the second surface is provided with an oxide film and a nitride film stacked in layers.

16. The photoelectric conversion apparatus according to claim 1, wherein the semiconductor layer includes a plurality of concavo-convex structures disposed on the first surface.

17. The photoelectric conversion apparatus according to claim 16, wherein at least a part of the third wiring is contained in a region where the plurality of concavo-convex structures is formed in a planar view.

18. A photoelectric conversion system comprising:
a photoelectric conversion apparatus comprising an avalanche diode disposed in a semiconductor layer having a first surface and a second surface facing the first surface,
wherein the avalanche diode includes:
a first semiconductor region of a first conductivity type disposed at a first depth;
a second semiconductor region of a second conductivity type disposed at a second depth deeper from the second surface than the first depth;
a third semiconductor region disposed at an edge of the first semiconductor region in a planar view;
a first wiring connected to the first semiconductor region;
a second wiring connected to the second semiconductor region; and
a third wiring not connected to the semiconductor layer, at least a part of the third wiring overlapping with the third semiconductor region in a planar view, and
wherein a third voltage to be supplied to the third wiring is a value between a first voltage to be supplied to the first wiring and a second voltage to be supplied to the second wiring; and
a signal processing unit configured to generate an image by using a signal output by the photoelectric conversion apparatus.

19. A moving body including a photoelectric conversion apparatus comprising an avalanche diode disposed in a semiconductor layer having a first surface and a second surface facing the first surface,
wherein the avalanche diode includes:
a first semiconductor region of a first conductivity type disposed at a first depth;
a second semiconductor region of a second conductivity type disposed at a second depth deeper from the second surface than the first depth;
a third semiconductor region disposed at an edge of the first semiconductor region in a planar view;
a first wiring connected to the first semiconductor region;
a second wiring connected to the second semiconductor region; and
a third wiring not connected to the semiconductor layer, at least a part of the third wiring overlapping with the third semiconductor region in a planar view, and
wherein a third voltage to be supplied to the third wiring is a value between a first voltage to be supplied to the first wiring and a second voltage to be supplied to the second wiring,
the moving body comprising a control unit configured to control movement of the moving body by using a signal output by the photoelectric conversion apparatus.
